(19) United States
(12) Patent Application Publication
(10) Pub. No.: US 2009/0016036 A1
(43) Pub. Date: Jan. 15, 2009

(54) CONDUCTOR REINFORCEMENT FOR CIRCUIT BOARDS

(76) Inventors: Shaw Fong WONG, Butterworth (MY); Ian En Yoon CHIN, Tanjung Bunga (MY); Wei Keat LOH, Bayan Lepas (MY)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/777,943

(22) Filed: Jul. 13, 2007

(51) Int. Cl. H05K 7/12

(52) U.S. Cl. 361/768; 361/808

(57) ABSTRACT

Conductors of a printed circuit board have conductive flanges between pads and traces. In one embodiment, the flange has a maximum width at least one half the maximum width of the pad. It is believed that such an arrangement can significantly reduce fractures or other damage to the conductors of the printed circuit board that may result from stress applied to the board during testing or further assembly operations. Other embodiments are described and claimed.

### BACKGROUND

### Description of Related Art

Integrated circuits typically include various active and passive circuit elements which have been integrated into a piece of semiconductor material, often referred to as a die. One or more dies may, in turn, be encapsulated into a package 10 (FIG. 1), which is often mechanically and electrically connected to a printed circuit board 20 by a plurality of solder joints 22. In this example, the solder joints 22 are formed by an array of solder balls arranged in a grid, often referred to as a ball grid array (BGA).

FIG. 2 shows an example of a solder joint 22 between the package 10 and the board 20. To form the joint 22, a ball 30 of solder is formed to extend from a conductor such as a land 32 which is typically disposed on the exterior of the package 10. The balls 30 are arranged in an appropriate pattern such as a grid array. The package 10 is placed on the board 20 with the solder balls 30 of the package 10 engaging corresponding pads 34 of the board 20. The pads 34 are typically arranged in a pattern which matches that of the solder balls 30. The assembly may then be heated to a degree which permits the solder balls to melt. Once the solder cools and solidifies, the solder joint 22 is formed.

FIG. 3 shows a top view of a typical printed circuit board 20 in which a top solder resist layer has been removed for clarity. The exposed surface 40 of the board 20 has various conductors formed thereon including the aforementioned pads 34 and also has plated vias 42 which interconnect various layers of the printed circuit board 20. As best seen in the schematic diagram of FIG. 4, other conductors include traces 44 which interconnect various pads 34 and plated vias 42. As shown in FIGS. 3 and 4, the pads 34 are typically generally circular or oval in shape. The traces 44 are generally elongated in shape and have a generally constant width.

### BRIEF DESCRIPTION OF THE DRAWINGS

Referring now to the drawings in which like reference numbers represent corresponding parts throughout:

FIG. 1 schematically illustrates a package mounted on a prior art printed circuit board;

FIG. 2 illustrates a pad of the printed circuit board of FIG. 1, connected to the package in a solder joint;

FIG. 3 illustrates an exposed surface conductors of the printed circuit board of FIG. 1;

FIG. 4 schematically illustrates an enlarged view of top surface conductors of the printed circuit board of FIG. 3;

FIG. 5 illustrates one example of a system employing a printed circuit board in accordance with one aspect of the present description;

FIG. 6 illustrates a pad of a printed circuit board in accordance with one aspect of the present description, connected to a package in a solder joint;

FIG. 7 is a schematic drawing of one example of conductors suitable for a printed circuit board in accordance with one aspect of the present description;

FIG. 8 depicts an enlarged schematic drawing of conductors of FIG. 6;

FIG. 9 is a flow chart depicting one example of operations for assembling devices utilizing a printed circuit board in accordance with one embodiment of the present description;

FIG. 10 schematically illustrates an enlarged view of conductors for a printed circuit board in accordance with another embodiment of the present description; and

FIG. 11 schematically illustrates an enlarged view of conductors for a printed circuit board in accordance with still another embodiment of the present description.

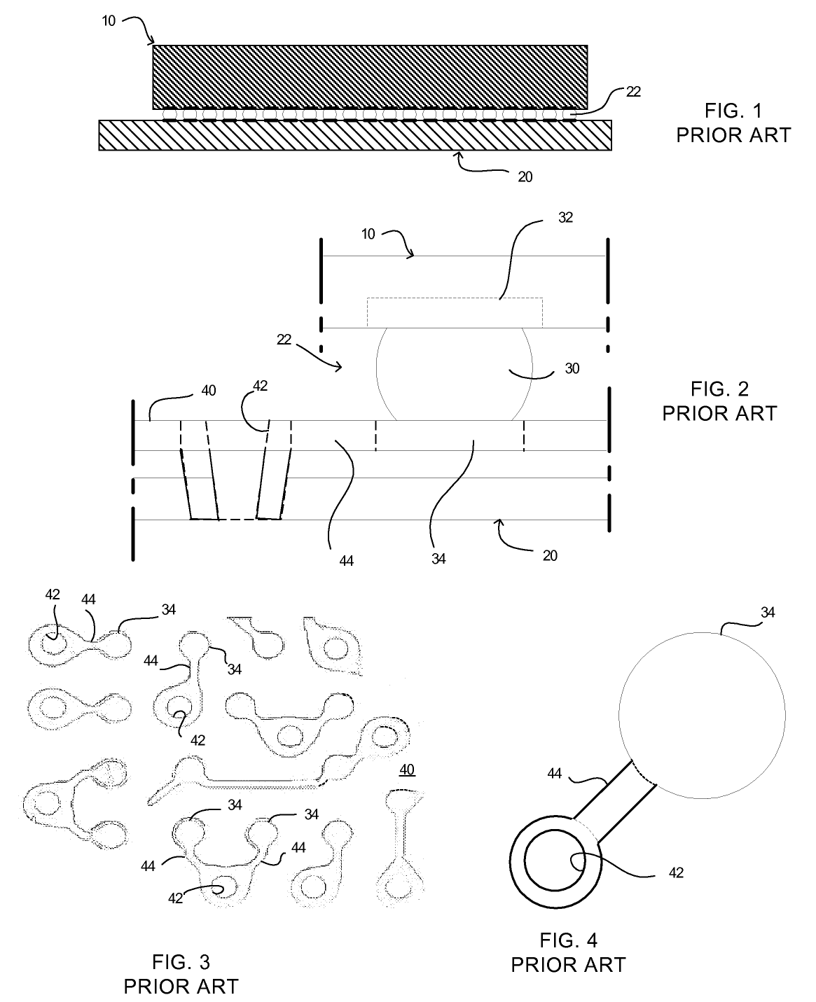

### DETAILED DESCRIPTION OF THE ILLUSTRATED EMBODIMENTS

In the following description, reference is made to the accompanying drawings which form a part hereof and which illustrate several embodiments of the present disclosure. It is understood that other embodiments may be utilized and structural and operational changes may be made without departing from the scope of the present description.

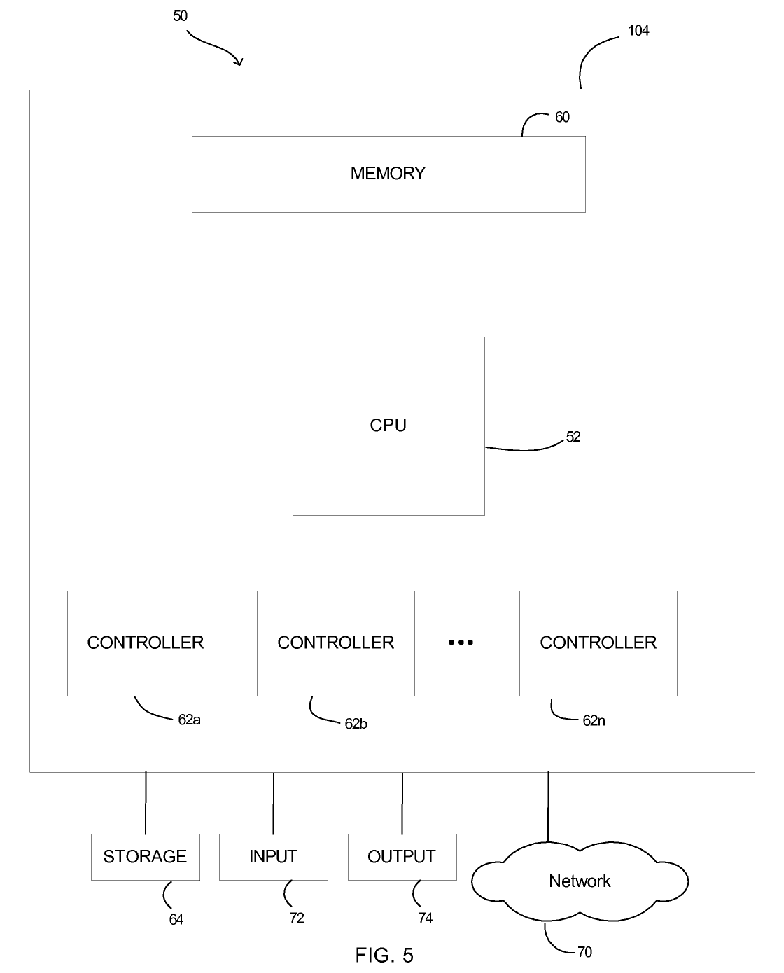

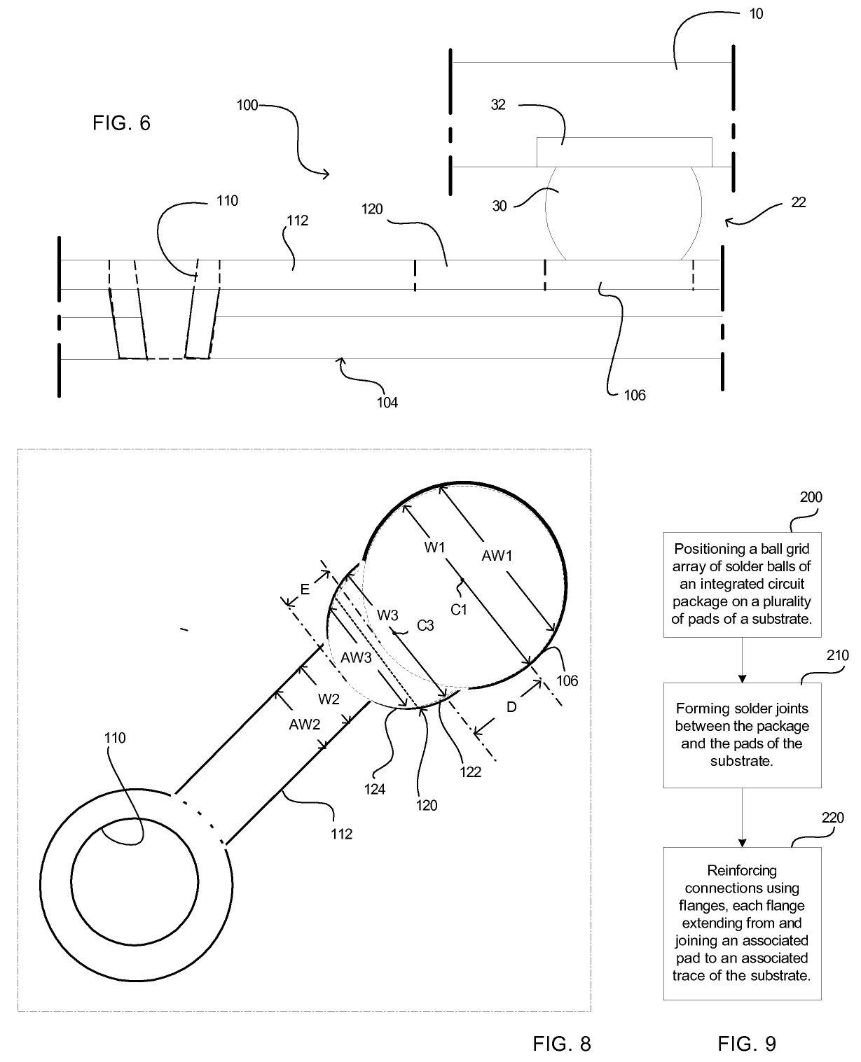

FIG. 5 illustrates an example of a computing environment in which aspects of described embodiments may be embodied. A computer 50 includes one or more electronic devices including a central processing units (CPU) 52 (only one is shown), a memory 60 (e.g., a volatile memory device), and a plurality of controllers 62a, 62b . . . 62n. One or more of the CPU 52, memory 60 and controllers 62a, 62b . . . 62n are disposed in one or more packages which are disposed on one or more printed circuit boards or other substrates. One such device is represented by an electronic device 100 (FIG. 6) which includes an integrated circuit package 10 and a printed circuit board 104 on which the package 10 is electrically and mechanically coupled by a plurality of solder joints 22 similar to the solder joints 22 of FIG. 2.

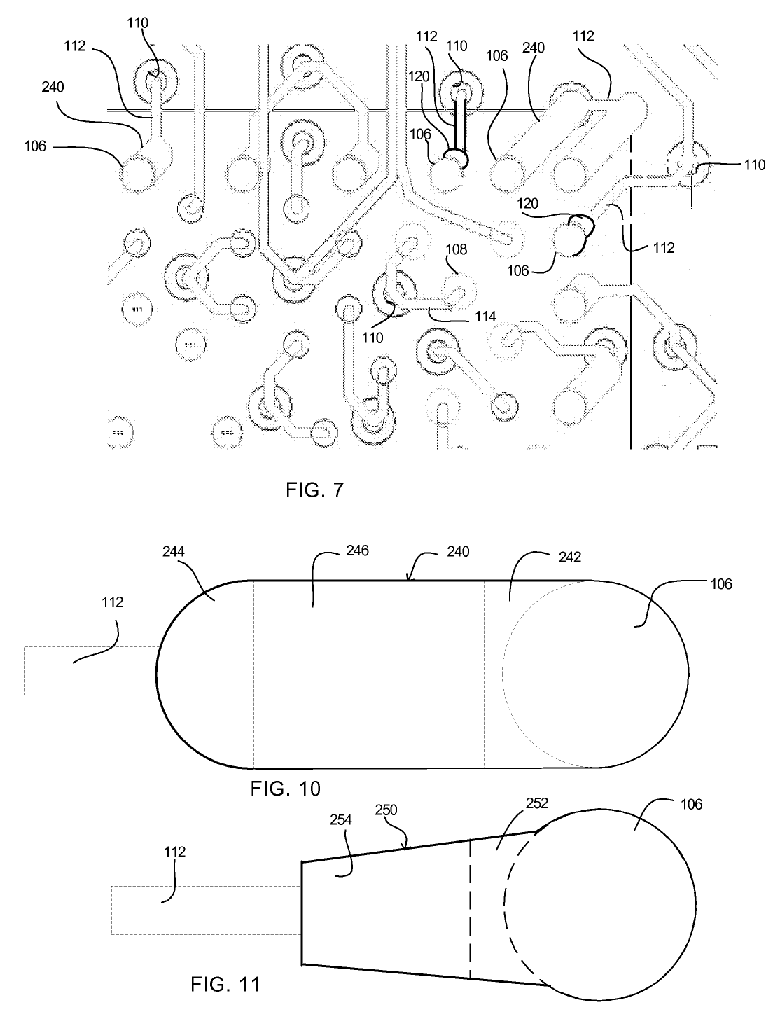

As shown in FIG. 7, the printed circuit board 104 has a plurality of conductors including pads 106, 108, plated vias 110 and traces 112, 114 interconnecting the various conductors. FIG. 8 schematically shows an example of one such pad 106 electrically coupled by a trace 112 to a plated via 110. In accordance with one aspect of the present description, the printed circuit board 104 further has a plurality of conductive flanges, an example of which is indicated at 120, which reinforce adjacent conductors. As explained in greater detail below, it is believed that such an arrangement can significantly reduce fractures or other damage to the conductors of the printed circuit board 104 that may result from stress applied to the board 104 during testing or further assembly operations. It is appreciated that in other applications, features other than fracture reduction may be realized in addition thereto or instead of, in utilizing a conductor flange in accordance with the present description.

The printed circuit board 104 may be a single layer or multi-layered motherboard which has a plurality of conductors that provide communication between the circuits in the device 100 and other components mounted to the board 104. Alternatively, one or more of the CPU 52, memory 60 and controllers 62a, 62b . . . 62n may be disposed on other substrates such as daughter cards or expansion cards or any other substrate suitable for supporting a die, package or other substrate.

An operating system and various applications execute on the CPU 52 and reside in the memory 60. The content residing in memory 60 may be cached in accordance with appropriate caching techniques. Programs and data in memory 60 may be swapped into storage 64 (e.g., a non-volatile storage, such as magnetic disk drives, optical disk drives, a tape drive, etc.) as part of memory management operations. The computer 50 may comprise any computing device, such as a mainframe, server, personal computer, workstation, laptop, handheld computer, telephony device, network appliance, virtualization device, storage controller, network controller, etc.

Any suitable CPU 52 and operating system may be used. For example, CPU 52 may represent any of a wide variety of control logic including, but not limited to one or more of a microprocessor, a programmable logic device (PLD), programmable logic array (PLA), application specific integrated circuit (ASIC), a microcontroller, and the like, although the present description is not limited in this respect. In one embodiment, CPU 52 includes one or more Intel® compatible processors. Processors of CPU 52 may have an instruction set containing a plurality of machine level instructions that may be invoked, for example by an application or operating system.

The controllers 62a, 62b . . . 62n may include a system controller, peripheral controller, memory controller, hub controller, I/O bus controller, video controller, network controller, storage controller, etc. For example, a storage controller can control the reading of data from and the writing of data to the storage 64 in accordance with a storage protocol layer. The storage protocol of the layer may be any of a number of suitable storage protocols. Data being written to or read from the storage 64 may be cached in accordance with appropriate caching techniques.

A network controller can include one or more protocol layers to send and receive network packets to and from remote devices over a network 70. The network 70 may comprise a Local Area Network (LAN), the Internet, a Wide Area Network (WAN), Storage Area Network (SAN), etc. Embodiments may be configured to transmit data over a wireless network or connection. In certain embodiments, the network controller and various protocol layers may employ the Ethernet protocol over unshielded twisted pair cable, token ring protocol, Fibre Channel protocol, etc., or any other suitable network communication protocol. In some embodiments, the computer 50 may not be connected to a network 70 or may lack storage 64.

A video controller can render information on a display monitor, and may be embodied on a video card or integrated on integrated circuit components mounted on the motherboard. Certain of the devices may have multiple cards or controllers. An input device 72 is used to provide user input to the computer 50, and may include a keyboard, mouse, pen-stylus, microphone, touch sensitive display screen, or any other suitable activation or input mechanism. An output device 74 is capable of rendering information transmitted from the processor CPU 52, or other component, such as a display monitor, printer, storage, speaker, etc.

In certain embodiments, a circuit board embodiment having one or more reinforcement flanges in accordance with the present description may be embodied in a computer system including a video controller to render information to display on a monitor coupled to a computer system comprising a desktop, workstation, server, mainframe, laptop, handheld computer, etc. Alternatively, the circuit board embodiments may be embodied in a computing device that does not include a video controller, such as a switch, router, etc.

A network controller or other devices described herein may be mounted on an expansion card, such as a Peripheral Component Interconnect (PCI) card, PCI-express or some other I/O expansion card coupled to a motherboard, or on integrated circuit components mounted on the motherboard. Integrated circuit dies may be packaged individually, or packaged with other dies in stacks or other arrangements within a package. Thus, circuit board embodiments may be embodied in computer systems or other systems in which one or more reinforcement flanges in accordance with the present description are disposed on one or both of a motherboard and an expansion card. Accordingly, in some system embodiments, the system may lack an expansion card, and a reinforcement flange in accordance with the present description may be disposed on a motherboard. In another system embodiment, a reinforcement flange in accordance with the present description may be disposed on an expansion card but not on a motherboard.

Details on the PCI architecture are described in “PCI Local Bus, Rev. 2.3”, published by the PCI-SIG. Details on the Fibre Channel architecture are described in the technology specification “Fibre Channel Framing and Signaling Interface”, document no. ISO/IEC AWI 14165-25. Details on the Ethernet protocol are described in publications including “IEEE std. 802.3,” published Mar. 8, 2002, and “IEEE std. 802.11,” published 1999-2003.

The conductors of the board 104, including the pads 106, traces 112, plated vias 110 and reinforcement flanges 120, may be formed by any suitable process including those known to practitioners skilled in the art of circuit board fabrication. For example, the conductors may be formed utilizing solder mask defined (SMD) or metal defined (MD) techniques or any other suitable process. Still further, the conductors of the board 104, including the pads 106, traces 112, plated vias 110 and flanges 120, may be formed of any suitable conductive material, including metals such as copper, silver, gold, aluminum or any alloy thereof, or any other material capable of conducting electrical signals.

In the device 100 of the illustrated embodiment, each pad 106 is generally round in shape. More particular, the pad 106 of FIG. 8 is circular in shape. The pad 106 defines a maximum width W1 which is equal to the diameter of the pad for a circular pad. For example, the pad 106 may have a diameter in a range of 16-20 mils (thousands of an inch) such as 20 mils. The pad further defines an average width AW1 which is less than the maximum width W1. It is appreciated that the pad may have other shapes such as oval and also nonround shapes such as square, rectangular, octagon, irregular etc. For an oval shape, for example, the maximum width W1 would be equal to the major axis of the oval shape.

Also, each trace 112 is generally elongated and defines a second maximum width W2 adjacent each pad 106. In the illustrated embodiment, the trace 112 has a generally constant width adjacent the pad 106. Hence, the average width AW2 of the trace 112 is substantially equal to the maximum width W2 of the trace 112 adjacent the pad 106. As best seen in FIG. 7, the traces 112, 114 often are oriented at a 45 degree angle to the rectangular array of pads 106, 108. It is appreciated that the traces may have other orientations and other shapes such as curved, trapezoidal, irregular, etc.

In the illustrated embodiment, the reinforcement flange 120 of FIG. 8 is generally crescent shaped and defines a third maximum width W3. In accordance with one aspect of the present description, the maximum width W3 of the flange 120 is at least one half of the maximum width W1 of the pad 106. For example, the diameter of the flange 120 may be approximately ⅔ the diameter of the pad 106. In another example, the maximum width W3 of the flange 120 may range from approximately ¾ths of the maximum width W1 of the pad 106 to approximately 100% of the width W1 of the pad 106. Such arrangements are believed to reduce fractures or other connection failures which may be caused by stress or flexure of the board 104 during testing or further assembly. It is appreciated that other relative sizes of the reinforcement flange and the pad may be suitable, depending upon the particular application.

The reinforcement flange 120 includes a concave portion 122 which extends from the pad 106, and a convex portion 124 which extends to the trace 112, thereby electrically coupling the pad 106 to the trace 112. In addition, the flange 120 structurally reinforces the pad 106 and the trace 112 adjacent to the pad 106.

As best seen in FIG. 8, the flange 120 defines an average width AW3 which is less than the average width AW1 of the pad 106 but greater than the average width AW2 of the trace 112. Again, it is appreciated that other relative sizes of the reinforcement flange, pad and trace may be suitable for reducing stress fractures or other failures, depending upon the particular application.

In another aspect of the present description, the pad 106 defines a center C1 and the reinforcing flange 120 defines a center C3 which is offset from the center C1 of the pad 106 by a distance D. In one embodiment, the center C3 of the flange 120 may be offset a distance D approximately ⅓ to ¼ the pad maximum width W1 of the pad 106. In another example, the flange 120 may overlap the pad 106 by 25-75% to provide an extruded or extended appearance as shown. Again, it is appreciated that other positions of the reinforcement flange, pad and trace may be suitable for reducing stress fractures or other failures, depending upon the particular application.

In yet another aspect of the present description, the flange 120 extends from the pad 106 to the trace 112 by a distance E. In one embodiment, the flange may extend a distance E approximately ⅓ to ¼ the pad maximum width W1 of the pad 106. For example, the flange may extend a distance E approximately equal to 5-8 mils. Again, it is appreciated that other relative sizes of the reinforcement flange, pad and trace may be suitable for reducing stress fractures or other failures, depending upon the particular application.

It is further appreciated that pads 106 may be selected for reinforcement with reinforcement flanges in a manner which depends upon the particular application. Thus, in the embodiment of FIG. 7, for example, pads 106 at the corners and edges of the array of pads 106, 108 may be selected for reinforcement as shown, in those applications in which assembly or testing stresses may be greatest at the corners or edges.

FIG. 9 shows one example of operations to assemble a device such as a circuit board and one or more packages which include various integrated circuits interconnected as a system. Such a system may include for example, a central processing unit, a memory coupled to the central processing unit, a video controller coupled to the central processing unit, storage coupled to the central processing unit, an input device coupled to the central processing unit, and an output device coupled to the central processing unit. In one operation, a ball grid array of solder balls of an integrated circuit package is positioned (block 200) on a plurality of pads of a substrate which has a plurality of traces. For example, in the illustrated embodiment, each pad 106 of the printed circuit board 104 has a first maximum width W1 and is electrically connected to an associated trace 112 which has a second maximum width W2 adjacent the pad 106.

In another operation, solder joints are formed (block 210) between the package and pads of the substrate wherein each solder joint joins a solder ball to an associated pad of the substrate. In the illustrated embodiment, the package 10 is placed on the board 104 with the solder balls 30 of the package 10 engaging corresponding pads 106, 108 of the board 104. The pads 106, 108 are typically arranged in a pattern which matches that of the solder balls 30. The assembly may then be heated to a degree which permits the solder balls to melt. Once the solder cools and solidifies, the solder joint 22 is formed.

In yet another operation, connections between pads and traces are reinforced (block 220) using flanges, each flange being disposed on the substrate and extending from and joining an associated pad to an associated trace. In the illustrated embodiment, each flange has a third maximum width W3 at least one half the width of the first maximum width W1 of the pads. For example, the diameter of the flange 120 may be approximately ⅔ the diameter of the pad 106. As another example, the diameter of the flange 120 may be approximately equal to the diameter of the pad 106. Such an arrangement is believed to reduce fractures or other connection failures which may be caused during straining, stress or flexure of the board 104 during testing or further assembly.

FIG. 10 shows another embodiment in which a flange 240 includes a concave portion 242 extending from a pad 106, a convex portion 244 extending to a trace 112, and an elongated intermediate portion 246 extending between the concave portion 242 and the convex portion 244. In this embodiment, the width of the concave portion 242, the width of the elongated intermediate portion 246 and the diameter of the convex portion 244 are substantially equal to each other and to the diameter of the pad 106. It is appreciated that other relative sizes of the reinforcement flange portions, pad and trace may be suitable for reducing stress fractures or other failures, depending upon the particular application.

FIG. 11 shows yet another embodiment in which a flange 250 includes a concave portion 252 extending from a pad 106, and a generally trapezoidal portion 254 extending from the concave portion 252 to a trace 112. In this embodiment, the average width of the flange 250 tapers such that the average width of the concave portion 252 is less than the diameter of the pad 106, and the average width of the elongated intermediate portion 256 is less than the average width of the concave portion 252. It is appreciated that other relative sizes of the reinforcement flange portions, pad and trace may be suitable for reducing stress fractures or other failures, depending upon the particular application.

### Additional Embodiment Details

The illustrated operations of FIG. 9 show certain events occurring in a certain order. In alternative embodiments, certain operations may be performed in a different order, modified or removed. Moreover, operations may be added to the above described operations and still conform to the described embodiments. Further, operations described herein may occur sequentially or certain operations may be processed in parallel.

The foregoing description of various embodiments has been presented for the purposes of illustration and explanation. It is not intended to be exhaustive or to limit to the precise form disclosed. Many modifications and variations are possible in light of the above teaching.

1. A device, comprising:
a printed circuit board, said board comprising:
a substrate having a surface; and
a plurality of surface conductors formed on said substrate surface, said surface conductors comprising:
an electrically conductive pad formed on said substrate surface, said pad having a first maximum width;
a generally elongated and electrically conductive trace formed on said substrate surface, said trace having a second maximum width adjacent said pad; and
an electrically conductive reinforcement flange formed on said substrate surface and extending from and joining said pad to said trace, said flange having a third maximum width at least one half the width of said first maximum width of said pad and electrically connecting said pad to said trace wherein said flange structurally reinforces said pad and said trace adjacent to said pad.

2. The device of claim 1 wherein said flange defines an average width greater than said second maximum width of said trace.

3. The device of claim 1 wherein said pad defines an average width greater than said average width of said flange.

4. The device of claim 1 wherein said pad is generally round in shape wherein said first maximum width defines one of a diameter and a major axis of said pad, and wherein said reinforcement flange is generally crescent shaped extending from said pad and said third maximum width defines one of a diameter and a major axis of said flange.

5. The device of claim 4 wherein said maximum width of said flange is approximately 2/3 of the maximum width of said pad.

6. The device of claim 4 wherein said pad defines a center and said flange defines a center offset from said pad center a distance approximately 1/3 to 1/4 said pad maximum width.

7. The device of claim 1 wherein said flange extends a distance from said pad to said trace, said distance being approximately 1/4 said first maximum width of said pad.

8. The device of claim 1 wherein said flange includes a concave portion extending from said pad, a convex portion extending to said trace and an elongated intermediate portion extending between said concave portion and said convex portion.

9. The device of claim 1 wherein said flange includes a concave portion extending from said pad, and a generally trapezoidal portion extending from said concave portion to said trace.

10. The device of claim 1 wherein said surface conductors include a plurality of said pads, a plurality of said traces and a plurality of said flanges, each flange being formed on said substrate surface and extending from and joining an associated pad to an associated trace.

11. The device of claim 10 further comprising a package having a die having an integrated circuit disposed in said package, and a ball grid array of solder joints, each solder joint being connected to a pad of said plurality of pads.

12. The device of claim 11 wherein said device is a computer system further comprising:
a central processing unit;
a memory coupled to said central processing unit;
a video controller coupled to said central processing unit;
storage coupled to said central processing unit;
an input device coupled to said central processing unit; and
an output device coupled to said central processing unit;
wherein said integrated circuit includes at least one of said central processing unit, memory, video controller, storage, input device, output device.

13. A method, comprising:
positioning a ball grid array of solder balls of an integrated circuit package on a plurality of pads of a plurality of surface conductors formed on a surface of a substrate of a printed circuit board, said surface conductors further including plurality of traces formed on said substrate surface, each pad having a first maximum width and being electrically connected by a connection to an associated trace of said plurality of traces, each trace having a second maximum width adjacent said pad;
forming solder joints between said package and said pads of said surface conductors on said substrate wherein each solder joint joins a solder ball to an associated pad of said surface conductors on said substrate; and
reinforcing connections using flanges of said surface conductors, each flange being formed on said substrate surface and extending from and joining an associated pad to an associated trace, each flange having a third maximum width at least one half the width of said first maximum width of said pads.

14. The method of claim 13 further comprising straining said substrate wherein said reinforcing is performed at least during said straining.

15. The method of claim 14 wherein said straining occurs during at least one of assembly and testing of a device which includes said printed circuit board.
